(19) United States
(12) Patent Application Publication
(10) Pub. No.: US 2017/0255510 A1
(43) Pub. Date: Sep. 7, 2017

(54) SYSTEM AND METHOD FOR REGENERATING CODES FOR A DISTRIBUTED STORAGE SYSTEM

(71) Applicant: Yunshang company limited, Shanghai City (CN)

(72) Inventors: Hai Bin KAN, Shanghai City (CN); Wei LIU, Shanghai City (CN)

(21) Appl. No.: 15/173,739

(22) Filed: Jun. 6, 2016

(30) Foreign Application Priority Data
Mar. 2, 2016 (CN) 201610116376.8

(51) Int. Cl. G06F 11/10; H03M 13/05; H03M 13/00

(52) U.S. Cl. CPC G06F 11/1044; H03M 13/6566; H03M 13/05

(57) ABSTRACT

An approach is provided for a system and a method for distributed storage based on regenerating codes. The system comprises a data source and multiple storage-nodes. The data source comprises a control module and an encoder. The control module segments data into multiple fragments. The encoder generates multiple data stripes from the fragments, in which each data stripe is generated according to a corresponding encoding vector and each of the encoding vectors is linearly independent to each other. The data source transmits each of the data stripes to one of the corresponding storage-nodes according to the encoding vectors. The data source receives an extension command configured for extending a selected storage-node, and generates an extension storage-node with a set of other randomly selected storage-node whereby to construct a linear combination with the data stripes and encoding vectors of the selected storage-nodes. The aforementioned extension storage node is homogeneous to the existing storage nodes.

### BACKGROUND

Technical Field

The disclosure is related to distributed storage, and more particularly, to a system and a method for distributed storage based on regenerating codes.

Related Art

A centralized network storage system is configured for storing all data in a storage server. The storage server itself becomes a limit of the performance of the network storage system, and keys for reliability and safety. Sometimes, the centralized network storage system cannot satisfy needs for massive storage solutions.

A distributed network storage system is another storage solution where data are distributed and stored on plural independent storage servers (also be referred as storage-nodes). Such a storage solution is scalable for increasing the number of storage servers for sharing the storage loadings, and all stored data can be manageable with location information by a location service device. Therefore, the distributed network storage system is not only scalable, but also has benefits of reliability, availability and accessibility.

In order to further increase the reliability of the distributed network storage system, regenerating codes are introduced to rebuild lost encoded fragments. The regenerating code is one of the erasure codes for error correction information theory. A recipient is able to detect and correct errors by the erasure codes when errors are encountered during the data transmission in networks.

Upon failure of an individual node, the regenerating codes repair the failed node by a replacement node. The replacement node needs to connect d nodes of the remaining nodes in the network, and download information with a size of P from each of these d nodes. Thus, the bandwidth of repair for regenerating codes is d*P. The bandwidth for rebuilding optimally trade models for regenerating codes includes a Minimum-Storage Regenerating (MSR) and a Minimum-Bandwidth Regenerating (MBR).

However, since the number of the storage-nodes in the conventional distributed network storage system is fixed, and the redundancy of the conventional distributed network storage system cannot be adjusted based on the characteristic of the stored data. Therefore, data transmission delay may occur when the data has been rapidly accessed.

### SUMMARY

These and other needs are addressed by the exemplary embodiments, in which one approach provides systems and methods for regenerating codes for a distributed storage system that is able to additionally assign extension storage-nodes when the encoded data has been transmitted to each one of the nodes.

According to an embodiment of the present disclosure, a system for a distributed storage system based on regenerating codes, in which encoded data is distributed to a plurality of storage-nodes and then extended to at least one extension storage-node, comprises a data source and multiple storage-nodes. The data source comprises a control module and an encoder. The control module segments data into multiple fragments. The encoder generates multiple data stripes from the fragments, where each data stripe is generated according a corresponding encoding vector, and each of the encoding vectors are linearly independent to each other. The data source transmits the data stripes to the corresponding storage-nodes according to the encoding vectors. The data source receives an extension command that is configured for extending a selected storage-node, and generates at least one extension storage-node with at least two other randomly selected storage-nodes whereby to construct a linear combination with the data stripes and encoding vectors of the selected storage-nodes.

According to another embodiment of the present invention, a method for distributed storage based on regenerating codes comprises steps of segmenting data into multiple fragments; encoding the fragments into a data stripe according to an encoding vector; transmitting and storing the data stripe and the corresponding encoding vector to a storage-node; selecting one of the storage-nodes as a specified storage-node when an extension command is received; and selecting a set of other storage-nodes, and generating an extension storage-node according to the selected storage-nodes, the encoding vectors and the data stripe.

Wherein the extension storage-node is homogeneous to the existing storage-nodes, in the sense that the extension command can be configured repeatedly using a fixed number of arbitrary existing nodes, regardless if they are generated by the data source, or previously extended from other nodes.

Compared with the regenerating codes system in the art, the present invention has at least the following advantages:

(1) The regenerating codes system in the art use fixed numbers for storage-nodes. The present invention has advantages of lowering the bandwidth, a higher encoding efficiency, a low computing cost and being able to adapt to a highly condition changes of the dynamic network; and

(2) The present invention can be applied to block storage, distribution and encoding modules of a distributed storage system. The corresponding storage system is more suitable for the system in which the access frequency of data is highly dynamic.

Still other aspects, features, and advantages of the exemplary embodiments are readily apparent from the following detailed description, simply by illustrating a number of particular embodiments and implementations, including the best mode contemplated for carrying out the exemplary embodiments. The exemplary embodiments are also capable of other and different embodiments, and their several details can be modified in various obvious respects, all without departing from the spirit and scope of the exemplary embodiments. Accordingly, the drawings and description are to be regarded as illustrative, and not as restrictive.

### BRIEF DESCRIPTION OF THE DRAWINGS

The present invention will become more fully understood from the detailed description given herein below for illustration only, and thus not limitative of the present invention, wherein:

FIG. 1A is an exemplary diagram of illustrating a structure of a distributed storage;

FIG. 1B is an exemplary diagram of illustrating a structure of data transmission in accordance with an embodiment of the present invention;

FIG. 2 is a flow chart of illustrating steps for regenerating codes for a distributed storage system in accordance with an embodiment of the present invention;

FIG. 3A is an exemplary diagram of illustrating embodiment of fragments and data stripes;

FIG. 3B is an exemplary diagram of illustrating data recovery of the storage-nodes; and

FIG. 4 is an exemplary diagram of illustrating a generation of an extension storage-node.

### DETAIL DESCRIPTION

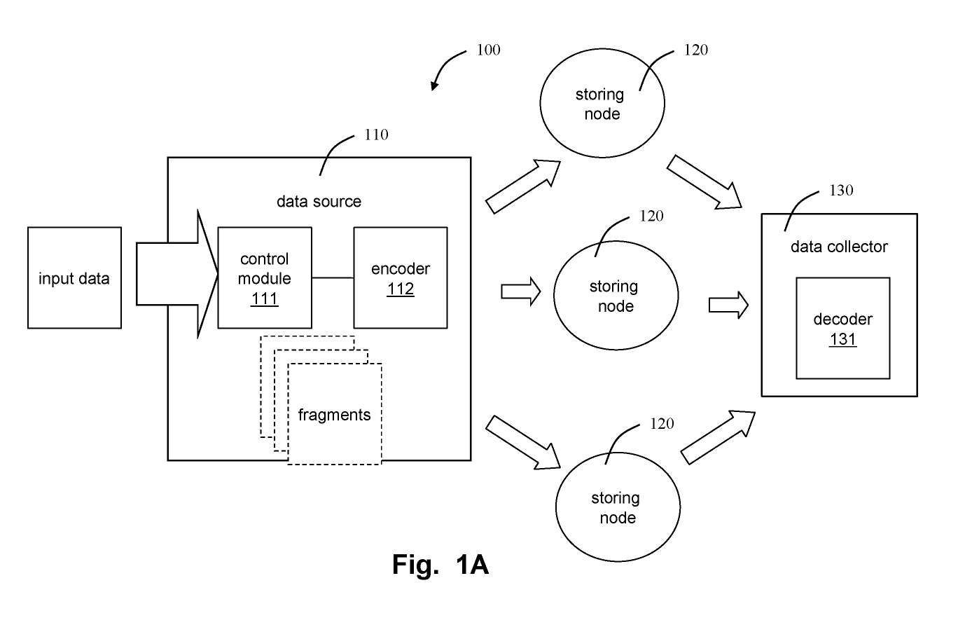

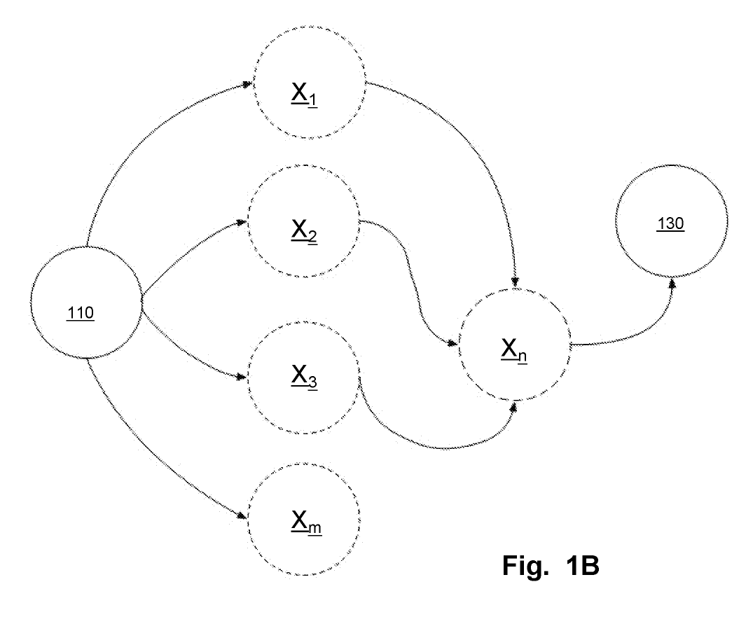

Referring to FIGS. 1A and 1B, FIG. 1A is an exemplary diagram of illustrating a structure of a distributed storage system based on regenerating codes in accordance with an embodiment of the present invention; and FIG. 1B is an exemplary diagram of illustrating a structure of data transmission in accordance with an embodiment of the present invention.

As shown in FIG. 1A, a distributed storage system 100 based on regenerating codes comprises a data source 110 and multiple storage-nodes 120. The data source 110 is defined hereinafter as a front-end interface for receiving input data of the distributed storage system 100. The data source 110 may be, not limited to, a disk drive, the Internet or a human-computer interface. The storage-nodes 120 are connected to the data source in a network manner.

The data source 110 comprises a control module 111 and an encoder 112. The control module 111 segments a data into multiple fragments. The encoder 112 has a vector matrix. The vector matrix has multiple encoding vectors. The encoder 112 selects one of the encoding vectors from the vector matrix. The encoder 112 generates a data stripe of the corresponding fragment according to the selected encoding vector, and each of the encoding vectors is non-linear to each other. Multiple data stripes form a main striping, and each data stripe has at least one fragment.

The data source 110 transmits the data stripes to the corresponding storage-nodes 120 according to the different encoding vectors. The storage-nodes 120 are configured for storing the data stripes and may be a hard disk, a Solid State Disk (SSD) or a flash storage device.

As shown in FIG. 1B, the data source 110 is illustrated on the left hand side, and a data collector 130 is illustrated on the right hand side. Multiple storage-nodes 120 are defined between the data source 110 and the data collector 130. The data collector 130 comprises a decoder 131. The decoder 131 decodes the data stripes received from the storage-nodes 120 into the fragments.

In one embodiment, the size of input data is defined as “B”, “d” is the number of the storage-nodes 120 that is needed for configuring an extension storage-node, and “a” is defined as the number of fragments contained in one single stripe.

For example, if B=4, a=2, d=3, and each storage-node 120 is configured to store 1 data stripe. That is, a data is segmented into 4 fragments, each storage-node 120 is allowed to store 2 fragments, and 3 storage-nodes 120 are required for generating an extension storage-node. FIG. 1B shows such embodiment that the storage-nodes 120 are identically marked as X₁, X₂, X₃, Xₘ, which X₁, X₂, X₃ are selected for configuring an extension storage-node Xₙ.

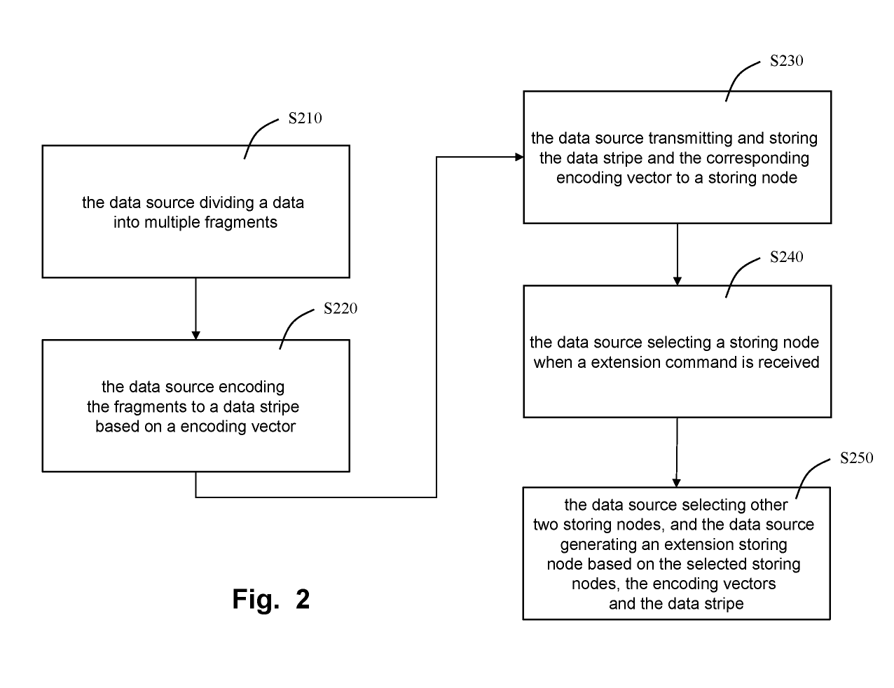

With reference to FIG. 2, in order to make Examiner fully understand the process for generating fragments and the data stripe, assume one data stripe 120 can only store two fragments. In this embodiment, a method for distributed storage based on regenerating codes, which the data source comprises acts of:

S210: segmenting data into multiple fragments;

S220: encoding the fragments into a data stripe according to an encoding vector;

S230: transmitting and storing the data stripe and the corresponding encoding vector to a storage-node;

S240: selecting one of the storage-nodes as a specified storage-node when an extension command is received; and

S250: selecting two of the other storage-nodes to generate an extension storage-node based on the selected storage-nodes, the encoding vectors and the data stripe.

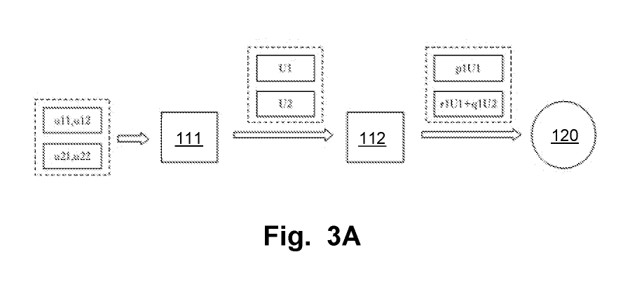

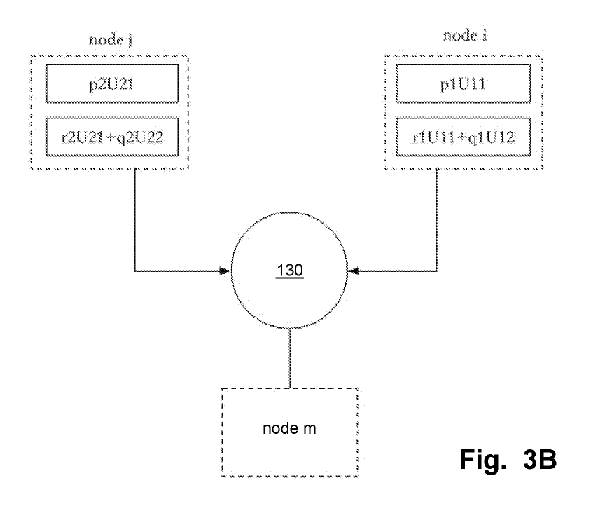

Assuming there are k storage-nodes 120, each storage-node is labeled as nodeᵢ, wherein i≦k. As above mentioned, B=4, a=2 and d=3, for example, the data has 4 fragments (u₁₁, u₁₂, u₁₃, and u₁₄). In this embodiment, each storage-node is able to store 1 data stripe, and each data stripe has two fragments. As shown in FIG. 3A, the fragments u₁₁, u₁₂, u₁₃, and u₁₄ are able to form vectors

$${U}_{1}^{t} , {U}_{2}^{t} [ \begin{matrix}{p}_{1}^{t} {U}_{1} \\ {r}_{1}^{t} {U}_{1} + {q}_{1}^{t} {U}_{2}\end{matrix} ] , and ( \begin{matrix}{u}_{11} & {u}_{12} \\ {u}_{21} & {u}_{22}\end{matrix} ) = ( \begin{matrix}{U}_{1}^{t} \\ {U}_{2}^{t}\end{matrix} )$$

from two fragments.

Wherein pᵢ^{t} is the encoding vector of U₁ vector of i^{th} storage-node, qᵢ^{t} is the encoding vector of U₂ vector of i^{th} storage-node, rᵢ^{t} is the encoding vector for compensating fragments of i^{th} storage-node. In addition, any of two encoding vectors {pᵢ^{t}}ᵢ₌₁ⁿ, {qᵢ^{t}}ᵢ₌₁ⁿ are non-linear.

The data source 110 then transmits the encoded data stripe and the encoding vector to the corresponding storage-node. The storage-node stores the data stripe and the encoding vector. When the data collector 130 detects that one of the storage-nodes is disabled (failed), the data collector 130 recovers the data of the disabled storage-node based on other existing storage-nodes and data stripes. With further reference to FIG. 3B, in an embodiment, when nodeₘ is disabled, the data collector 130 selects two other active storage-nodes nodeᵢ, nodeⱼ. The nodeᵢ, and nodeⱼ store two data stripes, which respectively are

$$[ \begin{matrix}{p}_{i}^{t} {U}_{1} \\ {r}_{i}^{t} {U}_{1} + {q}_{i}^{t} {U}_{2}\end{matrix} ] , [ \begin{matrix}{p}_{j}^{t} {U}_{1} \\ {r}_{j}^{t} {U}_{1} + {q}_{j}^{t} {U}_{2}\end{matrix} ] .$$

According to the encoding vectors of nodeᵢ, nodeⱼ, a 4×4 matrix is determined from the two data stripes as following:

| u₁₁ | u₁₂ | u₂₁ | u₂₂ |
|---|---|---|---|
| pᵢ₁ | pᵢ₂ | 0 | 0 |
| pⱼ₁ | pⱼ₂ | 0 | 0 |
| rᵢ₁ | rᵢ₂ | qᵢ₁ | qᵢ₂ |
| rⱼ₁ | rⱼ₂ | qⱼ₁ | qⱼ₂ |

When the 4×4 matrix is a non-singular matrix, the 4 fragments (u₁₁, u₁₂, u₁₃, and u₁₄) is determined by using linear substitutions. Since two encoding vectors {pᵢ^{t}}ᵢ₌₁ⁿ, {qᵢ^{t}}ᵢ₌₁ⁿ are non-linear, the two diagonally 2×2 blocks of the 4×4 matrix are non-singular matrix. The value rᵢ^{t} configured for recovering the encoding data does not have linear relationship, and thus the value can be given randomly. Accordingly, the data collector is able to retrieve information of the disabled storage-node based on the aforementioned calculations.

The present invention is not only recovering the data from the disabled storage-node, but also extends a specified storage-node. The extension storage-node can be configured to clone the information from the specified storage-node through other storage-nodes. The data stripe of the extension storage-node is homogeneous to the data stripe of the selected storage-node.

Accordingly, since the extension storage-node is homogeneous to the existing storage-nodes. The extension command can be configured repeatedly using a fixed number of arbitrary existing nodes, regardless if they are generated by the data source, or previously extended from other nodes.

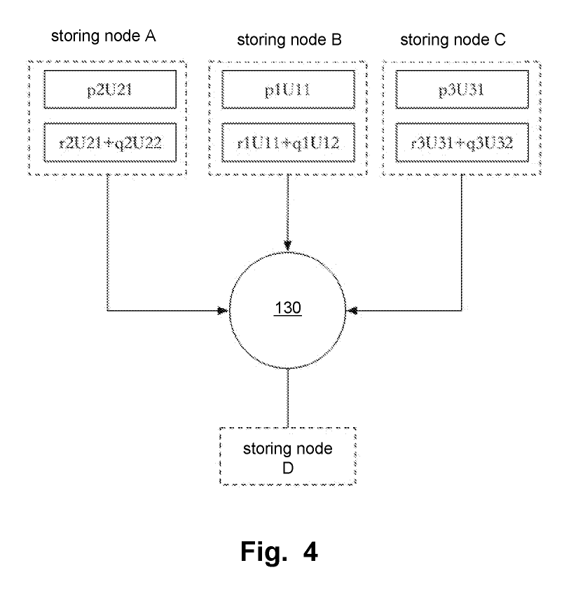

Referring to FIG. 4, in an embodiment, The storage-node A, the storage-node B and the storage-node D are considered to be used for extending the storage-node, and storage-node D is defined as an extension storage-node. The data stripe stored in the storage-node A, the storage-node B and storage-node C are λ₁p₁^{t}U₁+r₁^{t}U₁+q₁^{t}U₂, λ₂p₂^{t}U₁+r₂^{t}U₁+q₂^{t}U₂, and λ₃p₃^{t}U₁+r₃^{t}U₁+q₃^{t}U₂ respectively. In other words, the fragments stored in each of the storage-nodes are linear combination of the data source. Accordingly, in order to generate a new extension storage-node D, at least three fragments are required for the data collector 130 to obtain pᵢ^{t}U₁ and rᵢ^{t}U₁+qᵢ^{t}U₂. The following equations show the calculations for extending the storage-node:

$$\begin{matrix}[ \begin{matrix}{k}_{1} & {k}_{2} & {k}_{3}\end{matrix} ] [ \begin{matrix}{λ}_{1} {p}_{1}^{t} {U}_{1} + {r}_{1}^{t} {U}_{1} + {q}_{1}^{t} {U}_{2} \\ {λ}_{2} {p}_{2}^{t} {U}_{1} + {r}_{2}^{t} {U}_{1} + {q}_{2}^{t} {U}_{2} \\ {λ}_{3} {p}_{3}^{t} {U}_{1} + {r}_{3}^{t} {U}_{1} + {q}_{3}^{t} {U}_{2}\end{matrix} ] = {p}_{i}^{t} {U}_{1} & ( 1 ) \\ [ \begin{matrix}{l}_{1} & {l}_{2} & {l}_{3}\end{matrix} ] [ \begin{matrix}{λ}_{1} {p}_{1}^{t} {U}_{1} + {r}_{1}^{t} {U}_{1} + {q}_{1}^{t} {U}_{2} \\ {λ}_{2} {p}_{2}^{t} {U}_{1} + {r}_{2}^{t} {U}_{1} + {q}_{2}^{t} {U}_{2} \\ {λ}_{3} {p}_{3}^{t} {U}_{1} + {r}_{3}^{t} {U}_{1} + {q}_{3}^{t} {U}_{2}\end{matrix} ] = {r}_{i}^{t} {U}_{1} + {q}_{i}^{t} {U}_{2} & ( 2 )\end{matrix}$$

The equations of (3) and (4) can be determined from (1), which are

$$\begin{matrix}[ \begin{matrix}{q}_{1} & {q}_{2} & {q}_{3}\end{matrix} ] [ \begin{matrix}{k}_{1} \\ {k}_{2} \\ {k}_{3}\end{matrix} ] = 0 & ( 3 ) \\ [ \begin{matrix}{λ}_{1} {p}_{1} + {r}_{1} & {λ}_{2} {p}_{2} + {r}_{2} & {λ}_{3} {p}_{3} + {r}_{3}\end{matrix} ] [ \begin{matrix}{k}_{1} \\ {k}_{2} \\ {k}_{3}\end{matrix} ] = {p}_{i} & ( 4 )\end{matrix}$$

Since any two vectors of {qᵢ^{t}}ᵢ₌₁ⁿ are non-linear related, which:

$$[ \begin{matrix}{k}_{1} \\ {k}_{2}\end{matrix} ] = - {[ \begin{matrix}{q}_{1} & {q}_{2}\end{matrix} ]}^{- 1} {k}_{3} {q}_{3} \qquad ( 5 )$$

in combination (5) into (4) to get:

$$( [ \begin{matrix}{p}_{1} & {p}_{2}\end{matrix} ] [ \begin{matrix}{λ}_{1} & 0 \\ 0 & {λ}_{2}\end{matrix} ] + [ \begin{matrix}{r}_{1} & {r}_{2}\end{matrix} ] ) ( - {[ \begin{matrix}{q}_{1} & {q}_{2}\end{matrix} ]}^{- 1} {k}_{3} {q}_{3} ) = {p}_{i} - {k}_{3} ( {λ}_{3} {p}_{3} + {r}_{3} ) \qquad ( 6 )$$

and it can be rewritten as:

[PΛ+R](−Q⁻¹k₃q₃)=pᵢ−k₃(λ₃p₃+r₃) (7)

Λ is a 2×2 diagonal matrix where P=[p₁ p₂], Q=[q₁ q₂] and R=[r₁ r₂]. The equation of (7) can further simply into:

PΛQ⁻¹k₃q₃=k₃(λ₃p₃+r₃)−RQ⁻¹k₃q₃−pᵢ (8)

ΛQ⁻¹k₃q₃=P⁻¹(k₃(λ₃p₃+r₃)−RQ⁻¹k₃q₃−pᵢ) (9)

k₁, k₂, k₃ and λ₁, λ₂, λ₃ can be determined by giving any values to λ₃ and k₃ is not equal to zero. It is also noted that when solving equations, the vector of Q¹q₃^{t} will not have “0” element, otherwise it means that at least two vectors of {qᵢ^{t}}ᵢ₌₁ⁿ are linear.

$$\begin{matrix}[ \begin{matrix}{q}_{1} & {q}_{2} & {q}_{3}\end{matrix} ] [ \begin{matrix}{l}_{1} \\ {l}_{2} \\ {l}_{3}\end{matrix} ] = {q}_{i} & ( 10 ) \\ [ \begin{matrix}{λ}_{1} {p}_{1} + {r}_{1} & {λ}_{2} {p}_{2} + {r}_{2} & {λ}_{3} {p}_{3} + {r}_{3}\end{matrix} ] [ \begin{matrix}{l}_{1} \\ {l}_{2} \\ {l}_{3}\end{matrix} ] = {r}_{i} & ( 11 )\end{matrix}$$

$$[ \begin{matrix}{l}_{1} \\ {l}_{2}\end{matrix} ] = {[ \begin{matrix}{q}_{1} & {q}_{2}\end{matrix} ]}^{- 1} ( {q}_{i} - {l}_{3} {q}_{3} )$$

can be determined from equation (10), and l₁, l₂ can be determined by giving any value to l₃, wherein l₃ is not equal to zero.

Moreover, equation (11) can be solved by giving known values of k₁, k₂, k₃, λ₁, λ₂, λ₃, l₁, l₂ and l₃.

Accordingly, the extension storage-node D is able to store/clone the fragment and corresponding vector which were previous stored in other storage-node.

While the exemplary embodiments have been described in connection with a number of embodiments and implementations, the exemplary embodiments are not so limited but cover various obvious modifications and equivalent arrangements, which fall within the purview of the appended claims. Although features of the exemplary embodiments are expressed in certain combinations among the claims, it is contemplated that these features can be arranged in any combination and order.

What is claimed is:

1. A distributed storage system based on regenerating codes, in which encoded data is distributed to a plurality of storage-nodes and then extended to at least one extension storage-node, and the system comprising:
a data source comprising
a control module, for segmenting data into a plurality of fragments; and
an encoder, for generating a plurality of data stripes from the fragments, wherein each of the fragment is generated according to an corresponding encoding vector and the encoding vectors are linearly independent to each other; and
a plurality of storage-nodes, connected to the data source, wherein the data source transmits the data stripes to corresponding storage-nodes according to the encoding vectors;
wherein the data source receives an extension command configured for extending selected storage-nodes selected from the storage-nodes, the data source selects randomly at least two other storage-nodes from the plurality of storage-nodes, and the data source generates at least one extension storage-node which is a linear combination of the data stripes and encoding vectors of the selected storage-nodes; and
wherein the extension storage-node is homogeneous to the existing storage-nodes.

2. The system as claimed in claim 1, wherein the data stripes form a main striping and each data stripe includes at least one of the fragments.

3. The system as claimed in claim 1, wherein the encoder includes a vector matrix with the encoding vectors and randomly selects one of the encoding vectors from the vector matrix.

4. The system as claimed in claim 1, wherein the storage-node is a hard disk, a Solid State Disk, or a flash storage device.

5. The system as claimed in claim 1, further comprising a data collector connected to the data source and the storage-nodes in a network manner, wherein the data collector comprises a decoder for decoding the data stripes into the fragments.

6. The system as claimed in claim 1, wherein each of the storage-node stores at least one data stripe.

7. The system as claimed in claim 1, wherein the data stripe of the extension storage-node is homogeneous to the data stripe of the selected storage-node.

8. A method for distributed storage base on regenerating codes, in which encoded data is distributed to a plurality of storage-nodes and then extended to at least one extension storage-node, and the data source comprising steps of:
segmenting data into a plurality of fragments;
encoding the fragments into a data stripe according to an encoding vector;
transmitting and storing the data stripe and the corresponding encoding vector to one of the storage-nodes;
selecting one of the storage-nodes as a specified storage-node when an extension command is received; and
selecting at least two other storage-nodes to generate at least one extension storage-node according to the selected specified storage-nodes, the encoding vectors and the data stripe.

9. The method as claimed in claim 8, wherein the data stripe of the extension storage-node is homogeneous to the data stripe of the specified storage-node.

10. The method as claimed in claim 8, further comprising a step of randomly selecting an encoding vector from a vector matrix with plural encoding vectors, for encoding the fragments into the data stripe.
